(19) United States
(12) Patent Application Publication
(10) Pub. No.: US 2012/0267644 A1
(43) Pub. Date: Oct. 25, 2012

(54) ORGANIC LIGHT EMITTING DIODE DISPLAY

(76) Inventors: Se-Jin Cho, Yongin-city (KR); Chang-Ho Lee, Yongin-city (KR); Il-Soo Oh, Yongin-city (KR); Hee-Joo Ko, Yongin-city (KR); Hyung-Jun Song, Yongin-city (KR); Jin-Young Yun, Yongin-city (KR); Bo-Ra Lee, Yongin-city (KR); Young-Woo Song, Yongin-city (KR); Jong-Hyuk Lee, Yongin-city (KR); Sung-Chul Kim, Yongin-city (KR)

(21) Appl. No.: 13/238,985

(22) Filed: Sep. 21, 2011

(30) Foreign Application Priority Data
Apr. 21, 2011 (KR) 10-2011-0037380

(51) Int. Cl. H01L 33/62

(52) U.S. Cl. 257/88; 257/E33.062

(57) ABSTRACT

An organic light emitting diode (OLED) display includes a substrate and an organic light emitting element on the substrate and including a first electrode, a plurality of organic emission layers on the first electrode and including at least one P-type impurity doped organic emission layer, and a second electrode on the plurality of organic emission layers.

### CROSS-REFERENCE TO RELATED APPLICATIONS

This application claims priority to and the benefit of Korean Patent Application No. 10-2011-0037380 filed in the Korean Intellectual Property Office on Apr. 21, 2011, the entire contents of which are incorporated herein by reference.

### BACKGROUND

1. Field

Embodiments of the present invention relate to an organic light emitting diode (OLED) display.

2. Description of Related Art

An organic light emitting diode (OLED) display is a self emissive display device that displays images with organic light emitting diodes.

The organic light emitting element includes an anode, a cathode, and an organic emission layer located therebetween, and the organic emission layer generates light by combining holes and electrons injected by the anode and the cathode.

An organic light emitting element operable by a dual mode has been recently developed. The dual mode based organic light emitting element emits light corresponding to a forward voltage applied to the organic light emitting element in a normal mode, and reflects light corresponding to a reverse voltage applied to the organic light emitting element in a reflective mode/quenching mode.

The above-noted dual mode organic light emitting element is described in U.S. Patent Application Publication “US2002/0027537.”

The organic emission layer of the organic light emitting element is generally 30 nm thick. However, when the organic emission layer is substantially 30 nm thick, photoluminescence caused by an outer light source is very weak in the reflective mode so the user has a problem in perceiving light emission.

Therefore, an organic emission layer with a thickness that is greater than 50 nm is used to improve optical efficiency in the reflective mode. However, as the organic emission layer becomes thicker, a driving voltage required for the organic light emitting element is increased such that luminance is deteriorated at the same voltage.

The above information disclosed in this Background section is only for enhancement of understanding of the background of the described technology and therefore it may contain information that does not form the prior art that is already known in this country to a person of ordinary skill in the art.

### SUMMARY

Embodiments of the present invention are directed to an organic light emitting diode (OLED) display with a dual mode organic light emitting element for efficiently providing a driving voltage.

An exemplary embodiment of the present invention provides an organic light emitting diode display including a substrate and an organic light emitting element on the substrate and including a first electrode, a plurality of organic emission layers on the first electrode and including at least one P-type impurity doped organic emission layer, and a second electrode on the plurality of organic emission layers.

The at least one P-type impurity doped organic emission layer may be between undoped organic emission layers of the plurality of organic emission layers.

The organic light emitting element may further include a P-type impurity doped hole transport layer (HTL) between the first electrode and the plurality of organic emission layers.

The organic light emitting element may further include at least one of an electron transport layer (ETL) and an electron injection layer (EIL) between the second electrode and the plurality of organic emission layers.

The plurality of organic emission layers may include a first organic emission layer on the first electrode, a P-type impurity doped second organic emission layer on the first organic emission layer and a third organic emission layer on the second organic emission layer.

The first organic emission layer and the third organic emission layer may each be 40 to 60 nm thick, and the second organic emission layer may be 10 to 20 nm thick.

The plurality of organic emission layers may further include a P-type impurity doped fourth organic emission layer on the third organic emission layer, and a fifth organic emission layer on the fourth organic emission layer.

The first organic emission layer, the third organic emission layer, and the fifth organic emission layer may each be 20 to 40 nm thick, and the second organic emission layer and the fourth organic emission layer may each be 10 to 20 nm thick.

The organic light emitting element may be operable in a dual mode including a normal mode and a reflective mode.

A forward voltage may be applied to the organic light emitting element in the normal mode, and a reverse voltage may be applied to the organic light emitting element in the reflective mode.

According to an embodiment of the present invention, the organic light emitting diode (OLED) display includes a dual mode organic light emitting element for efficiently controlling an increase of the driving voltage.

### BRIEF DESCRIPTION OF THE DRAWINGS

FIG. 1 and FIG. 2 show an operational state of a dual mode organic light emitting element used for an organic light emitting diode (OLED) display according to a first exemplary embodiment of the present invention.

FIG. 3 shows a cross-sectional view of an organic light emitting diode (OLED) display according to the embodiment represented in FIG. 1.

FIG. 4 shows a cross-sectional view of an organic light emitting diode (OLED) display according to a second exemplary embodiment of the present invention.

### DETAILED DESCRIPTION

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Like reference numerals designate like elements throughout the specification. In exemplary embodiments other than the first exemplary embodiment, elements different from those of the first exemplary embodiment will be described.

Further, the size and thickness of each of elements that are illustrated in the drawings are described for better understanding and ease of description, and the embodiments of the present invention are not limited to the described size and thickness.

In the drawings, the thickness of layers, films, panels, regions, etc., may be exaggerated for clarity. In the drawings, for better understanding and ease of description, thicknesses of some layers and areas may be excessively displayed. It will be understood that when an element such as a layer, film, region, or substrate is referred to as being “on” another element, it can be directly on the other element or one or more intervening elements may also be present.

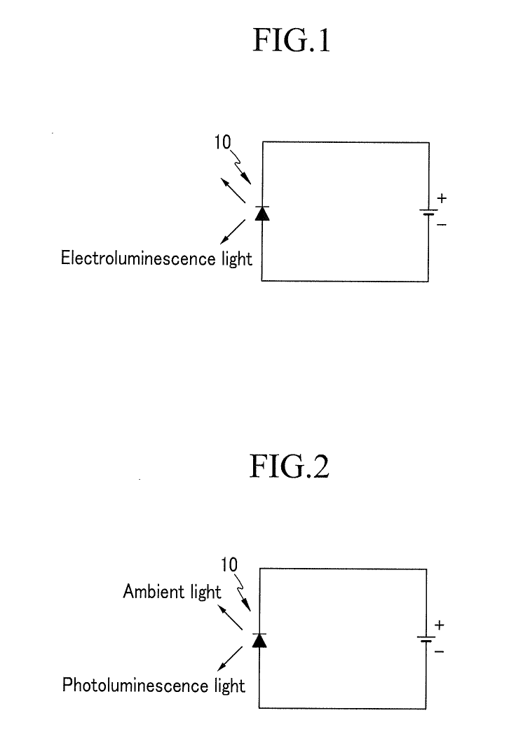

An organic light emitting diode (OLED) display 101 according to a first exemplary embodiment will now be described with reference to FIG. 1 to FIG. 3.

The organic light emitting diode (OLED) display 101 includes a dual mode organic light emitting element 10.

FIG. 1 shows a schematic circuit diagram when a dual mode organic light emitting element 10 according to an embodiment of the present invention is operable in a normal mode, and FIG. 2 shows a schematic circuit diagram when the same is operable in a reflective mode.

As shown in FIG. 1, when the dual mode organic light emitting element 10 of the present embodiment is operated according to the normal mode, a level of a voltage applied to an anode of the organic light emitting element 10 is greater than a level of a voltage applied to a cathode thereof. That is, when a forward voltage is applied to the dual mode organic light emitting element 10, the dual mode organic light emitting element 10 is operated in the normal mode.

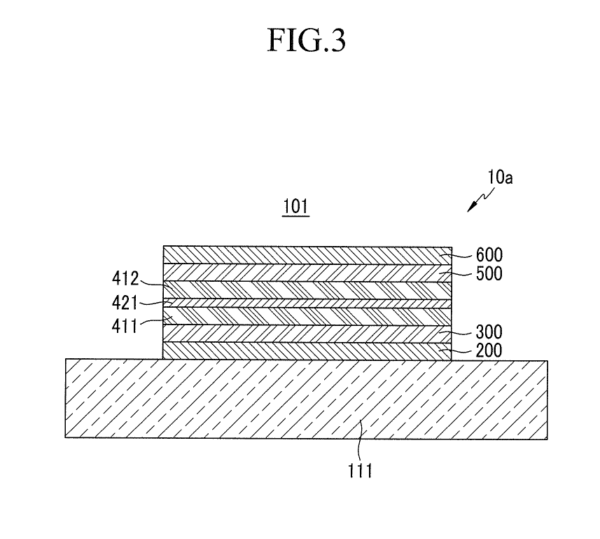

As the forward voltage applied to the organic light emitting element 10 is increased, the current flowing to the organic light emitting element 10 is increased, and the luminance of the light emitted is also increased. Therefore, the organic light emitting diode (OLED) display 101 (see FIG. 3) using the organic light emitting element 10 operable in the normal mode displays an image.

As shown in FIG. 2, when the dual mode organic light emitting element 10 is operated according to the reflective mode, a level of the voltage applied to the anode of the organic light emitting element is less than a level of the voltage applied to the cathode thereof. That is, when a reverse voltage is applied to the dual mode organic light emitting element 10, the dual mode organic light emitting element 10 is operated in the reflective mode.

As the reverse voltage applied to the organic light emitting element 10 is increased, the current flowing to the organic light emitting element 10 is increased, and luminance is decreased. That is, as the reverse voltage becomes greater, the organic light emitting element 10 absorbs more light so an amount of reflected light is reduced. Resultantly, as the reverse voltage becomes greater, the organic light emitting element 10 becomes darker. Accordingly, the organic light emitting diode (OLED) display 101 using the organic light emitting element 10 operable in the reflective mode displays the image.

An organic light emitting element 10 used for the organic light emitting diode (OLED) display 101 according to the present embodiment will now be described with reference to FIG. 3.

As shown in FIG. 3, the organic light emitting element 10a is formed on a substrate 111. The substrate 111 may be, for example, a transparent insulating substrate made of glass, crystal, or ceramic, or a transparent flexible substrate made of plastic.

A first electrode 200 is located on the substrate 111. The first electrode 200 is a hole injection electrode, which is the anode. The first electrode 200 can be formed with various materials that are known to a person skilled in the art.

A hole transport layer (HTL) 300 is on the first electrode 200. A P-type impurity may be doped in the hole transport layer (HTL) 300. That is, in the present embodiment, the P-type impurity can be doped to the hole transport layer (HTL) made of a general material known to a person skilled in the art.

A plurality of organic emission layers 411, 421, and 412 are formed on the hole transport layer (HTL) 300. At least one of the plurality of organic emission layers 411, 421, and 412 is doped with the P-type impurity. In the present embodiment, the organic emission layer 421 to which the P-type impurity is doped is located between the organic emission layers 411 and 412 to which no impurity is doped.

In the present embodiment, the plurality of organic emission layers 411, 421, and 412 includes a first organic emission layer 411 formed on the hole transport layer (HTL) 300, a second organic emission layer 421 doped with the P-type impurity and formed on the first organic emission layer 411, and a third organic emission layer 412 formed on the second organic emission layer 421. In the present embodiment, the first organic emission layer 411 and the third organic emission layer 412 are 40 to 60 nm thick, and the second organic emission layer 421 is 10 to 20 nm thick.

At least one of an electron transport layer (ETL) or an electron injection layer (EIL) 500 is formed on the plurality of organic emission layers 411, 421, and 412.

A second electrode 600 is formed on the electron transport layer (ETL) or the electron injection layer (EIL) 500. The second electrode 600 is an electron injection electrode, which is the cathode. The second electrode 600 can be formed with various materials that are known to a person skilled in the art.

Further, the present embodiment is not restricted to the above-described configuration. Therefore, according to other embodiments of the present invention, the organic light emitting element 10 can omit at least one of the hole transport layer (HTL) 300, the electron transport layer (ETL), or the electron injection layer (EIL) 500. In addition, the organic light emitting element 10 can further include the hole injection layer (HIL) or other functional layers.

According to the configuration of the present embodiment, the organic light emitting diode (OLED) display 101 can include a dual mode organic light emitting element 10 for efficiently controlling (e.g., reducing) an increase of the driving voltage. That is, according to the present embodiment, a thickness of the organic emission layer (e.g., organic emission layers 411, 412, and 421) is sufficient for appropriate light emission in the reflective mode, and the P-type impurity doped organic emission layer (e.g., second organic emission layer 421) and the no impurity doped organic emission layer (e.g., the undoped organic emission layers 411 and 412) are alternately arranged, thereby efficiently controlling the increase of the driving voltage.

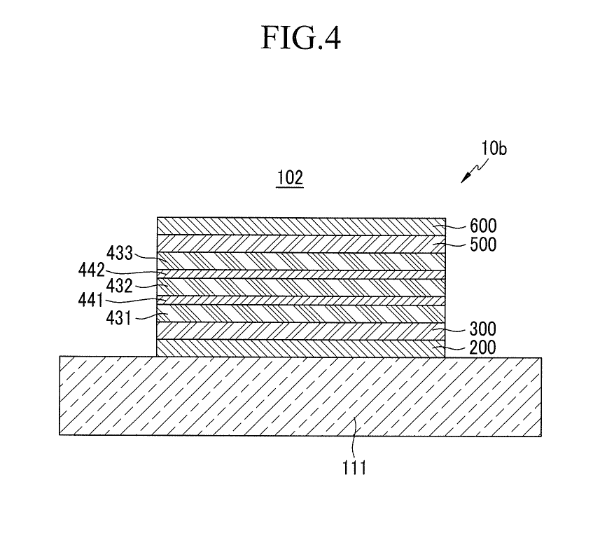

An organic light emitting diode (OLED) display 102 according to a second exemplary embodiment of the present invention will now be described with reference to FIG. 4.

As shown in FIG. 4, in the second exemplary embodiment of the present invention, a plurality of organic emission layers 431, 432, 433, 441, and 442 include a first organic emission layer 431 formed on the hole transport layer (HTL) 300, a second organic emission layer 441 formed on the first organic emission layer 431 and to which the P-type impurity is doped, a third organic emission layer 432 formed on the second organic emission layer 441, a fourth organic emission layer 442 formed on the third organic emission layer 432 and to which the P-type impurity is doped, and a fifth organic emission layer 433 formed on the fourth organic emission layer 442. Here, the first organic emission layer 431, the third organic emission layer 432, and the fifth organic emission layer 433 are 20 to 40 nm thick, and the second organic emission layer 441 and the fourth organic emission layer 442 are 10 to 20 nm thick.

According to the above-described configuration of the present embodiment, the organic light emitting diode (OLED) display 102 can include a dual mode organic light emitting element 10b for efficiently controlling (e.g., reducing) the increase of driving voltage.

An experimental example and a comparative example according to the first exemplary embodiment of the present invention will now be described with reference to Table 1.

In the experimental example, according to the first exemplary embodiment, the P-type impurity doped hole transport layer (HTL) having a thickness of 20 nm, the first organic emission layer having a thickness of 50 nm, the P-type impurity doped second organic emission layer having a thickness of 15 nm, the third organic emission layer having a thickness of 50 nm, the electron injection layer (EIL) having a thickness of 1 nm, and the second electrode are sequentially formed on the first electrode.

In the comparative example, a P-type impurity doped hole transport layer (HTL) having a thickness of 20 nm, an organic emission layer having a thickness of 100 nm, an electron injection layer (EIL) having a thickness of 1 nm, and a second electrode are sequentially formed on a first electrode.

TABLE 1

| | Voltage (V) | J (mA/cm2) | Cd/m2 | CIEx | CIEy |
|---|---|---|---|---|---|
| Experimental | 5 | 92.6575 | 359.7 | 0.6665 | 0.3325 |
| Example | | | | | |
| Comparative | 5 | 40.3275 | 138.9 | 0.6696 | 0.3295 |
| Example | | | | | |

As illustrated in Table 1, the experimental results show that the experimental example according to the first exemplary embodiment of the present invention has luminance and optical efficiency that are substantially 2.5 times better than those of the comparative example for the same driving voltage.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display comprising:
a substrate; and
an organic light emitting element on the substrate and comprising:
a first electrode;
a plurality of organic emission layers on the first electrode and comprising at least one P-type impurity doped organic emission layer; and
a second electrode on the plurality of organic emission layers.

2. The organic light emitting diode display of claim 1, wherein the at least one P-type impurity doped organic emission layer is between undoped organic emission layers of the plurality of organic emission layers.

3. The organic light emitting diode display of claim 2, wherein the organic light emitting element further comprises a P-type impurity doped hole transport layer (HTL) between the first electrode and the plurality of organic emission layers.

4. The organic light emitting diode display of claim 3, wherein the organic light emitting element further comprises at least one of an electron transport layer (ETL) and an electron injection layer (EIL) between the second electrode and the plurality of organic emission layers.

5. The organic light emitting diode display of claim 1, wherein the plurality of organic emission layers comprises:
a first organic emission layer on the first electrode;
a P-type impurity doped second organic emission layer on the first organic emission layer; and
a third organic emission layer on the second organic emission layer.

6. The organic light emitting diode display of claim 5, wherein the first organic emission layer and the third organic emission layer are each 40 to 60 nm thick, and the second organic emission layer is 10 to 20 nm thick.

7. The organic light emitting diode display of claim 5, wherein the plurality of organic emission layers further comprises:
a P-type impurity doped fourth organic emission layer on the third organic emission layer; and
a fifth organic emission layer on the fourth organic emission layer.

8. The organic light emitting diode display of claim 7, wherein the first organic emission layer, the third organic emission layer, and the fifth organic emission layer are each 20 to 40 nm thick, and the second organic emission layer and the fourth organic emission layer are each 10 to 20 nm thick.

9. The organic light emitting diode display of claim 1, wherein the organic light emitting element is operable in a dual mode comprising a normal mode and a reflective mode.

10. The organic light emitting diode display of claim 9, wherein a forward voltage is applied to the organic light emitting element in the normal mode, and a reverse voltage is applied to the organic light emitting element in the reflective mode.
